(19) United States
(12) Patent Application Publication
(10) Pub. No.: US 2015/0041104 A1
(43) Pub. Date: Feb. 12, 2015

(54) SYSTEMS AND METHODS FOR ROBUST AND MODULAR SYNTHETIC JET COOLING

(71) Applicants: GE Aviation Systems, LLC, Grand Rapids, MI (US); General Electric Company, Schenectady, NY (US)

(72) Inventors: Hendrik Pieter Jacobus De Bock, Clifton Park, NY (US); William Dwight Gerstler, Niskayuna, NY (US); Jonathan Mark Dunsdon, Glenville, NY (US); Stefano Angelo Mario Lassini, Lowell, MI (US); William Earl Gross, JR., Grand Rapids, MI (US); Delbert Warren Flaherty, Grand Rapids, MI (US); Randall Lee Neuman, Hudsonville, MI (US); Christina Clyde Schroeder, Byron Center, MI (US)

(21) Appl. No.: 13/963,473

(22) Filed: Aug. 9, 2013

(51) Int. Cl. H05K 7/20; F15C 4/00; B05B 17/06; F15C 3/16

(52) U.S. Cl. CPC H05K 7/20136; F15C 3/16; F15C 4/00; B05B 17/0653
USPC 165/104.34; 239/102.2

(57) ABSTRACT

A modular synthetic cooling jet apparatus for cooling at least one electronic component and including a first synthetic cooling jet is provided. The first synthetic cooling jet includes a first piezoelectric element, and a first pair of plates coupled to the first piezoelectric element. The first pair of plates includes a first top plate and a first bottom plate. The first synthetic cooling jet also includes a first air gap defined between the first top plate and the first bottom plate. The first flex circuit is coupled to the first piezoelectric element. The first flex circuit is configured to be coupled to an electrical power source and to transmit a first electrical signal to the first piezoelectric element. The first piezoelectric element is configured to actuate at least one of the first top plate and the first bottom plate to induce a first expelling air stream.

### BACKGROUND

The field of the disclosure relates generally to systems and methods for cooling electronic components, and more particularly to piezoelectric synthetic cooling jet systems.

Known systems for actively cooling electronic components, such as fans, typically include mechanical elements such as bearings and bushings. The fan operates to force air over the electronic components, facilitating cooling through forced convective heat transfer. However, the mechanical elements of the fan can wear over time posing a potential reduction in the reliability of the product. Additionally, significant challenges exist in reducing the dimensions of known systems to fit in modern electrical devices. As such, many known devices, e.g., without limitation, smart phones, select tablets, and passively cooled avionics, do not include active cooling systems.

To overcome this problem, some known devices utilize synthetic jets that can provide air movement without the use of typical moving mechanical elements. Synthetic jets are micro-fluidic devices that may be used to enhance convective heat transfer by generating an air stream using an electrically driven actuating element. Although the actuating elements of a synthetic jet can flex, there is no contact between moving surfaces, such as is typical in fans where bearings move within housings. Therefore, synthetic jets pose a different reliability profile than typical fans. However, known synthetic jets utilize wires to connect the actuating elements with an electrical source, reducing long-term durability. Known systems further utilize only a single wire connection to each of the actuating elements to the electrical source, increasing the likelihood that the synthetic jet will fail to operate correctly.

Also, known synthetic cooling jets operate as singular cooling elements. Therefore, known synthetic jets are limited in their cooling capacity by the air stream generated by a single synthetic cooling jet. The singular nature of known synthetic cooling jets limits the commercial applications to situations where a relatively low amount of cooling is required.

### BRIEF DESCRIPTION

In one aspect, a modular synthetic cooling jet apparatus for cooling at least one electronic component and including a first synthetic cooling jet is provided. The first synthetic cooling jet includes a first piezoelectric element, and a first pair of plates coupled to the first piezoelectric element. The first pair of plates includes a first top plate and a first bottom plate. The first synthetic cooling jet also includes a first air gap defined between the first top plate and the first bottom plate. The first flex circuit is coupled to the first piezoelectric element. The first flex circuit is configured to be coupled to an electrical power source and to transmit a first electrical signal to the first piezoelectric element. The first piezoelectric element is configured to actuate at least one of the first top plate and the first bottom plate to induce a first expelling air stream.

In another aspect, a method of cooling an electronic component is provided. The method includes receiving electrical power from an electrical power source at a first flex circuit of a first synthetic cooling jet, and transmitting a first electrical signal from the first flex circuit to a first piezoelectric element. The first piezoelectric element is coupled to a first pair of plates that comprise a first top plate and a first bottom plate, the first top plate and the first bottom plate defining a first air gap between the first top plate and the first bottom plate. The method also includes actuating at least one of the first top plate and the first bottom plate with the first piezoelectric element to induce a first expelling air stream, and facilitating cooling the electronic component with the first expelling air stream.

In yet another aspect, a synthetic cooling jet system is provided. The synthetic cooling jet system includes an electrical power source, an electronic component, and a first synthetic cooling jet. The first synthetic cooling jet includes a first piezoelectric element, and a first pair of plates coupled to the first piezoelectric element. The first pair of plates includes a first top plate and a first bottom plate. The first synthetic cooling jet also includes a first air gap defined between the first top plate and the first bottom plate, and a first flex circuit coupled to the first piezoelectric element. The first flex circuit is configured to be coupled to the electrical power source and to transmit a first electrical signal to the first piezoelectric element. The first piezoelectric element is configured to actuate at least one of the first top plate and the first bottom plate to induce a first expelling air stream that interacts with the electronic component.

### DRAWINGS

These and other features, aspects, and advantages of the present disclosure will become better understood when the following detailed description is read with reference to the accompanying drawings in which like characters represent like parts throughout the drawings, wherein:

FIG. 1 is a perspective view of an exemplary synthetic cooling jet;

FIG. 2 is a schematic view of the synthetic cooling jet shown in FIG. 1 illustrating an exemplary expansion and compression cycle;

FIG. 3 is an exploded view of an exemplary synthetic cooling jet system including a plurality of synthetic cooling jets shown in FIG. 1; and

FIG. 4 is a flow chart illustrating an exemplary method of cooling at least one electronic component implemented by the synthetic cooling jet system shown in FIG. 3.

Unless otherwise indicated, the drawings provided herein are meant to illustrate features of embodiments of the disclosure. These features are believed to be applicable in a wide variety of systems including one or more embodiments of the disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

Orienting language, as used herein throughout the specification and the claims, is solely used to facilitate the description of elements with respect to each other, and does not define their orientation with respect to any other frame of reference. Accordingly, elements modified by terms such as “top” and “bottom” may be oriented in any other direction with respect to an outside frame of reference unless the context or language clearly indicates otherwise.

Furthermore, references to one “implementation” or one “embodiment” of the subject matter described herein are not intended to be interpreted as excluding the existence of additional implementations that also incorporate the recited features.

The synthetic jet cooling systems described herein facilitate cooling an electronic component. The electronic component may be any electrical device including, e.g., without limitation, a heat sink, an integrated circuit, a package, a microprocessor, a CPU, or a network adapter. The embodiments described herein also facilitate providing a robust and durable synthetic cooling jet system with redundant connections. The embodiments described herein also facilitate increased cooling capacity through a modular synthetic cooling jet system.

The synthetic jet cooling system described herein includes an electrical power source and at least one synthetic cooling jet, e.g., without limitation, a dual piezoelectric cooling jet, coupled to the electrical power source. The at least one synthetic cooling jet includes a pair of plates, also referred to as shims and/or disks, and at least one piezoelectric element. The at least one piezoelectric element is coupled to at least one plate of the pair of plates. In some embodiments, the synthetic cooling jet includes a pair of piezoelectric elements coupled to a respective top plate and bottom plate of the pair of plates. The top plate and the bottom plate define an air gap between the top plate and the bottom plate and further define an orifice along a portion of the outer edge of the top plate and the bottom plate through which air can enter and be expelled.

The at least one synthetic cooling jet also includes at least one flex circuit coupled to at least one piezoelectric element and to the electrical power source. The at least one flex circuit receives power from the electrical power source, and transmits an electrical signal to the at least one piezoelectric element. In some embodiments, the synthetic cooling jet includes a top flex circuit and a bottom flex circuit coupled to a respective top plate and a respective bottom plate, each flex circuit also coupled to a respective top piezoelectric element and bottom piezoelectric element. When an electrical signal is applied to the at least one piezoelectric element, the piezoelectric element actuates at least one of the top plate and the bottom plate to bow, or flex, compressing and expanding the air gap. Each compression and expansion cycle induces an expelling air stream or an entering air stream respectively, in a manner similar to a bellows. In the exemplary embodiment, the synthetic cooling jets may be oriented such that the expelling air stream is directed toward the electronic component. The expelling air stream interacts with the air proximate the electronic component to facilitate forced convective heat transfer by the electronic component.

Furthermore, the exemplary synthetic cooling jet system may be modular. More specifically, the exemplary synthetic cooling jet system may include a plurality of synthetic cooling jets coupled to respective brackets. Each bracket includes an electrical contact through which an electrically conductive element may be inserted to electrically connect each of the plurality of synthetic cooling jets. In addition, the electrical contact may also electrically connect a flex circuit associated with a top piezoelectric element to a flex circuit associated with a bottom piezoelectric element. The modular synthetic cooling jet system may orient each of the plurality of synthetic cooling jets in substantially the direction of the electronic component to facilitate cooling the electronic component through forced convective heat transfer.

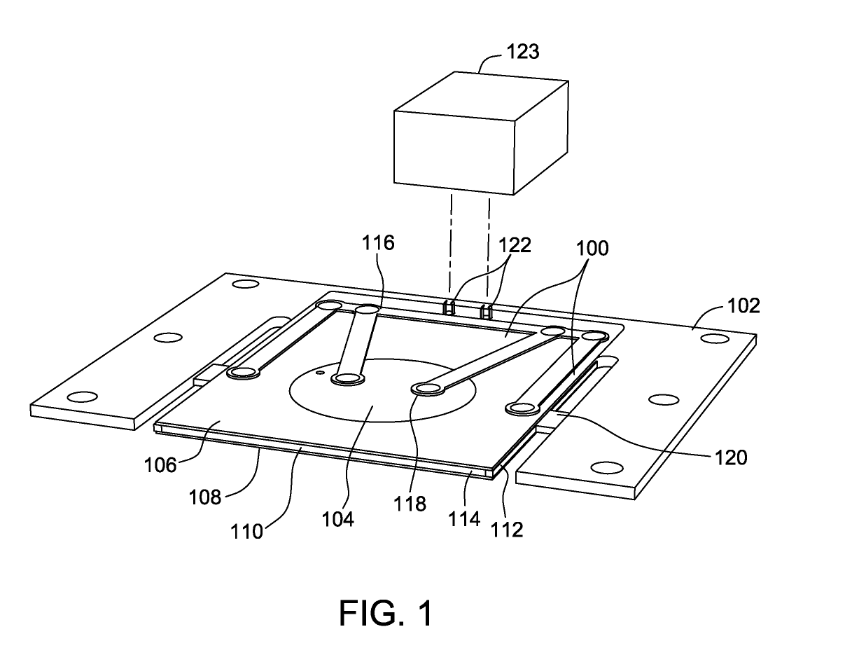

FIG. 1 is a perspective view of an exemplary synthetic cooling jet 100 coupled to a bracket 102. In the exemplary embodiment, synthetic cooling jet 100 includes at least one piezoelectric element 104 coupled to a pair of plates 106 and 108. A top plate 106 and a bottom plate 108 define an air gap 110 therebetween. Top plate 106 and bottom plate 108 further define an outer edge 112 along the perimeter of top plate 106 and bottom plate 108. In the exemplary embodiment, top plate 106 and bottom plate 108 are coupled along a portion of outer edge 112 by e.g., without limitation, silicone. Outer edge 112 of top plate 106 and bottom plate 108 defines at least one orifice 114 through which air enters and escapes air gap 110. In the exemplary embodiment, piezoelectric element 104 is also coupled to a flex circuit 116. In one implementation flex circuit 116 is coupled to piezoelectric element 104 at a plurality of contact pads 118, e.g., without limitation, sputtered contact pads 118. Alternatively flex circuit 116 is coupled to piezoelectric element at any contact pad that enables flex circuit 116 to operate as described herein.

Also in the exemplary embodiment, top plate 106 and bottom plate 108 are coupled to bracket 102 through a suspension 120. Bracket 102 partially circumscribes top plate 106 and bottom plate 108, and includes at least one electrical contact 122 capable of receiving at least one electrically conductive element (not shown in FIG. 1) e.g., without limitation, a pin, screw, electric conductive epoxy, bolt, clip, wire, or any other electrically conductive device that enables bracket 102 to support electrical connections through bracket 102. Electrical contact 122 may further be coupled to flex circuit 116 and/or an electrical power source 123. In at least some embodiments, synthetic cooling jet 100, bracket 102, and contact pads 118 are coated with a polymer, e.g., without limitation, parylene, to provide a protective coating around each of the elements and reduce arcs.

In the exemplary embodiment, synthetic cooling jet 100 is substantially symmetric. More specifically, in one implementation, top plate 106 is coupled to a top piezoelectric element 104 and a respective top flex circuit 116, and bottom plate 108 is coupled to a bottom piezoelectric element 104 and respective bottom flex circuit 116.

In the exemplary embodiment, piezoelectric element 104 receives an electrical signal, e.g, without limitation, an alternating current (AC) signal, from an electrical power source 123 through flex circuit 116. The applied electrical signal produces a change in the static dimensions of the piezoelectric element 104 through the piezoelectric effect. For example, the piezoelectric elements 104 may expand and/or contract based on the applied electrical signal. In one implementation, piezoelectric element 104 is fabricated with lead zirconate titanate. Alternatively, piezoelectric element 104 may be fabricated with any piezoelectric material that enables the synthetic cooling jet 100 to function as described herein.

In the exemplary embodiment, top plate 106 and bottom plate 108 are spaced apart from each other such that they define air gap 110 therebetween. Also in the exemplary embodiment, top plate 106 and bottom plate 108 are partially coupled along outer edge 112 of top plate 106 and bottom plate 108 using a material with a relatively high modulus, e.g., without limitation, silicone. Outer edge 112 of top plate 106 and bottom plate 108 defines an orifice 114 through which air can enter and exit air gap 110. In the exemplary embodiment, top plate 106 and bottom plate 108 are fabricated from Ni42 steel. Alternatively, top plate 106 and bottom plate 108 are fabricated from any material that enables top plate 106 and bottom plate 108 to function as described herein.

In the exemplary embodiment, a flex circuit 116 is coupled to electrical power source 123, piezoelectric element 104, and one of top plate 106 and bottom plate 108. More specifically, flex circuit 116 may be coupled to piezoelectric element 104 and one of top plate 106 and bottom plate 108 at a plurality of contact pads 118, e.g. without limitation, sputtered contact pads 118. Alternatively, flex circuit may be coupled to piezoelectric element 104 and one of top plate 106 and bottom plate 108 using any means that enables flex circuit 116 to operate as described herein. Flex circuit 116 may be formed by laminating copper between layers of polyester or other similar materials including polyimide, polyethylene napthalate, polyetherimide, or any combination thereof. In other embodiments, flex circuit 116 may be formed by a photolithographic process and/or any other process that enables flex circuit 116 to operate as described herein. In the exemplary embodiment, flex circuit 116 may be coupled to electrical power source 123 through bracket 102. Alternatively, flex circuit 116 may be coupled to electrical power source 123 directly.

In at least one embodiment, flex circuit 116 is redundantly coupled to at least one of piezoelectric element 104, top plate 106, and bottom plate 108 to facilitate improving the durability and robustness of synthetic cooling jet 100. More specifically, flex circuit 116 may be coupled at a plurality of contact pads 118 associated with piezoelectric element 104. Moreover, flex circuit may be redundantly coupled at a plurality of contact pads 118 associated with one of top plate 106 and bottom plate 108.

Also in the exemplary embodiment, flex circuit 116 may have an additional length, e.g., without limitation, by having a serpentine structure and/or a curved structure, to facilitate reducing the impedance of movement of top plate 106 and bottom plate 108.

Further in at least some embodiments, flex circuit 116 may be coupled to a plurality of piezoelectric elements 104. For example, flex circuit 116 may wrap around the back of bracket 102, connecting flex circuit 116 with a piezoelectric element 104 associated with top plate 106 and another piezoelectric element 104 associated with bottom plate 108. In other embodiment, a top flex circuit 116 associated with top plate 106 may be coupled to a bottom flex circuit 116 associated with bottom plate 108 through bracket 102.

Also in the exemplary embodiment, synthetic cooling jet 100 is coupled to bracket 102. In the exemplary embodiment, bracket 102 is a printed circuit board (PCB), a printed wiring board (PWB), a metallic board, or any combination thereof. Alternatively, bracket 102 may be fabricated from any material that enables bracket 102 to function as described herein. Bracket 102 partially circumscribing synthetic cooling jet 100, and includes at least one electrical contact 122 that enables connecting synthetic cooling jet 100 with other electrical components including, e.g., without limitation, another synthetic cooling jet 100. More specifically, electrical contact 122 is capable of receiving at least one electrically conductive element (not shown in FIG. 1) e.g., without limitation, a pin, screw, electric conductive epoxy, bolt, clip, wire, and/or any other electrically conductive device that enables bracket 102 to support electrical connections through bracket 102. In the exemplary embodiment, bracket 102 electrically connects a top flex circuit 116 that is coupled to top plate 106 to a bottom flex circuit 116 that is coupled to bottom plate 108. In the exemplary embodiment, electrical contact 122 is a press-fit contact. In some embodiments, bracket 102, can also contain additional components, such as a resistor (not shown), capacitor (not shown), or other logic that modifies or conditions the electrical signal transmitted to synthetic cooling jet 100.

In the exemplary embodiment, suspension 120 couples top plate 106 and bottom plate 108 to bracket 102. Moreover, suspension 120 facilitates damping a vibrational intensity of top plate 106 and bottom plate 108 as they are actuated by respective piezoelectric elements 104. In the exemplary embodiment, suspension 120 is fabricated from, e.g., without limitation, silicone. Alternatively, suspension 120 may be fabricated from other materials that enable suspension 120 to operate as described herein.

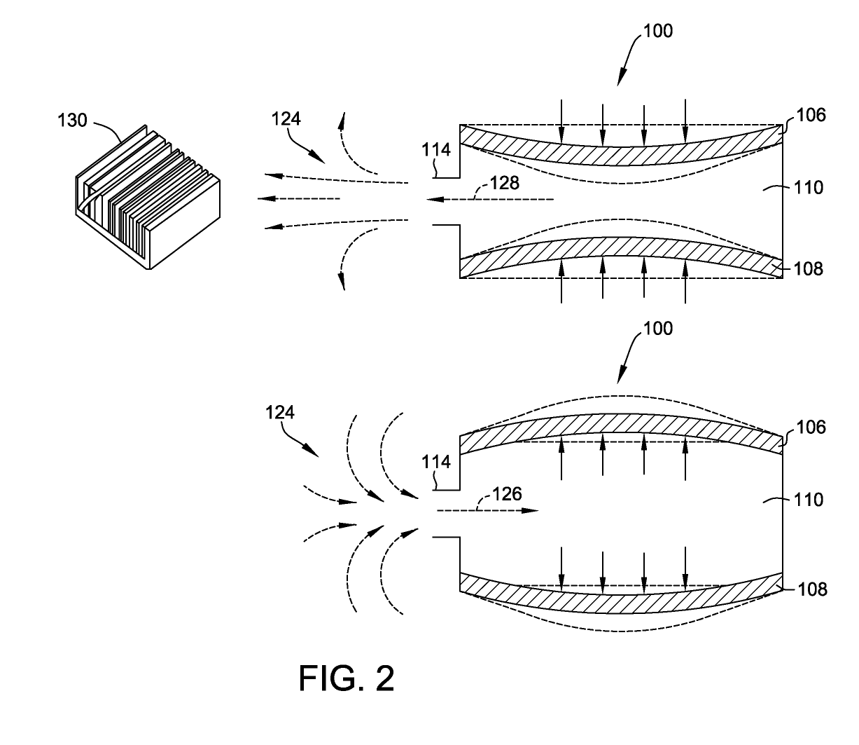

FIG. 2 is a schematic view of synthetic cooling jet 100 (shown in FIG. 1) undergoing an exemplary expansion cycle and compression cycle. In the exemplary embodiment, when piezoelectric element 104 (shown in FIG. 1) receives an electrical signal, the piezoelectric effect induces a deformation in the static structure of piezoelectric element 104 based on the applied signal. More specifically, the electrical power source 123 (shown in FIG. 1) applies an AC signal to piezoelectric element 104 causing expansion and compression of piezoelectric element 104 based on the polarity of the applied signal.

In the exemplary embodiment, a respective piezoelectric element 104 is coupled to each of top plate 106 and bottom plate 108, and at least one polarity induces respective piezoelectric elements 104 to expand, in turn inducing top plate 106 and bottom plate 108 to bow, or flex, in a radially outward direction away from the other, herein referred to as an “expansion cycle”. In such an embodiment, a volume of air in air gap 110 defined between top plate 106 and bottom plate 108 is expanded. Due to the increased volume of air gap 110, air pressure forces outside air 124 into air gap 110 as an entering air stream 126. In the exemplary embodiment, entering air stream 126 enters air gap 110 through orifice 114.

Also in the exemplary embodiment, at least one other polarity induces piezoelectric elements 104 to compress, in turn causing top plate 106 and bottom plate 108 to bow, or flex, in a radially inward direction toward each other, herein referred to as a “compression cycle”. In such an embodiment, a volume of air gap 110 is reduced. Due to the decreased volume of air gap 110, air pressure expels air inside air gap 110 through orifice 114 as an expelling air stream 128. Expelling air stream 128 entrains outside air 124 at least partially in the direction of an electronic component 130. In the exemplary embodiment, expelling air stream 128 may interact with at least one electronic component 130, facilitating convective heat transfer by electronic component 130. Electronic component 130 may be any electrical device including, e.g., without limitation, a heat sink, an integrated circuit, a package, a microprocessor, a CPU, or a network adapter.

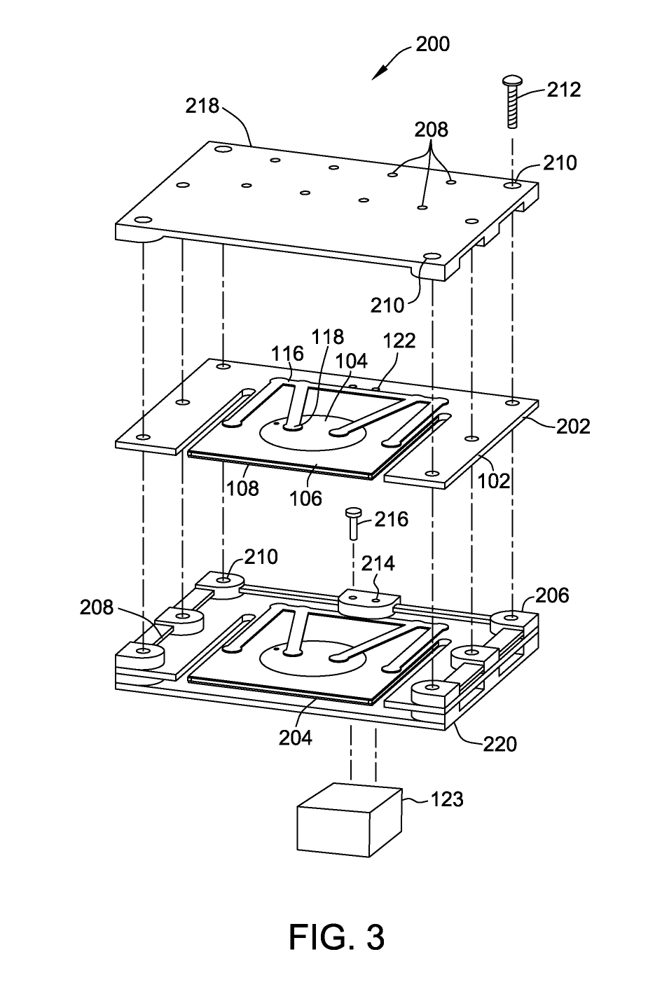

FIG. 3 is an exploded view of a synthetic cooling jet system 200 including a plurality of synthetic cooling jets 100 (shown in FIG. 1) coupled with electrical power source 123. More specifically, synthetic cooling jet system 200 includes a first synthetic cooling jet 202 and a second synthetic cooling jet 204. Each of first synthetic cooling jet 202 and second synthetic cooling jet 204 includes a bracket 102, at least one piezoelectric element 104, top plate 106, bottom plate 108, at least one flex circuit 116, contact pads 118, and electrical contact 122. Synthetic cooling jet system 200 may include any number of synthetic cooling jets 100 that enables synthetic cooling jet system 200 to operate as described herein.

In the exemplary embodiment, first synthetic cooling jet 202 is stacked with second synthetic cooling jet 204. In the exemplary embodiment, first synthetic cooling jet 202 and second synthetic cooling jet 204 are stacked in a vertical stack formation. Alternatively, first synthetic cooling jet 202 and second synthetic cooling jet 204 may be stacked in a horizontal stack formation and/or any other formation that enables the synthetic cooling jet system 200 to function as described herein. Also in the exemplary embodiment, the first synthetic cooling jet 202 and second synthetic cooling jet 204 are coupled to a spacer 206 positioned between first synthetic cooling jet 202 and second synthetic cooling jet 204. Spacer 206 defines an area between first synthetic cooling jet 202 and second synthetic cooling jet 204 and further defines at least one ventilation hole 208. In the exemplary embodiment, ventilation hole 208 facilitates the ventilation of air through each layer of synthetic cooling jets 100, and the ventilation of air facilitates reducing the temperature of synthetic cooling jet system 200. Ventilation holes 208 can be various shapes and dimensions to facilitate the movement of air through synthetic cooling jet system 200. Spacer 206 may further define a plurality of fastening holes 210 configured to receive at least one fastener 212, e.g., without limitation, a pin, screw, bolt, clip, adhesive, or any other device capable of fastening first synthetic cooling jet 202 to second synthetic cooling jet 204. In the exemplary embodiment, spacer 206 also defines a contact hole 214 that may receive at least one electrically conductive element 216. More specifically electrically conductive element 216 creates an electrical connection between respective electrical contacts 122 of first synthetic cooling jet 202 and second synthetic cooling jet 204.

Also in the exemplary embodiment, a cap assembly 218 is coupled to the top of synthetic cooling jet system 200 and a base assembly 220 is coupled to the bottom of synthetic cooling jet system 200. In the exemplary embodiment, cap assembly 218 includes a plurality of ventilation holes 208. Cap assembly 218 may also include a plurality of fastening holes 210. Base assembly 220 is coupled to second synthetic cooling jet 204, and includes a plurality of fastening holes 210 that facilitate fastening second synthetic cooling jet 204 to base assembly 220. In the exemplary embodiment, at least one fastening hole 210 extends from cap assembly 218 to base assembly 220, and facilitates coupling synthetic cooling jet system 200 to another device.

In the exemplary embodiment, synthetic cooling jet system 200 includes electronic component 130 (shown in FIG. 2) that is a heat sink (not shown) associated with, e.g., without limitation, an avionics structure (not shown). The heat sink is coupled to base assembly 220 with fasteners 212, and contains a plurality of cooling fins oriented opposite at least one air gap 110 associated with first synthetic cooling jet 202 and second synthetic cooling jet 204. The heat sink also provides a through heat sink electrical connection to the first flex circuit 116 and second flex circuit 116 associated with the first synthetic cooling jet 202 and second synthetic cooling jet 204, respectively. In operation, at least one of the plurality of synthetic cooling jets 100 facilitates cooling the heat sink by providing an expelling air stream that interacts with the cooling fins.

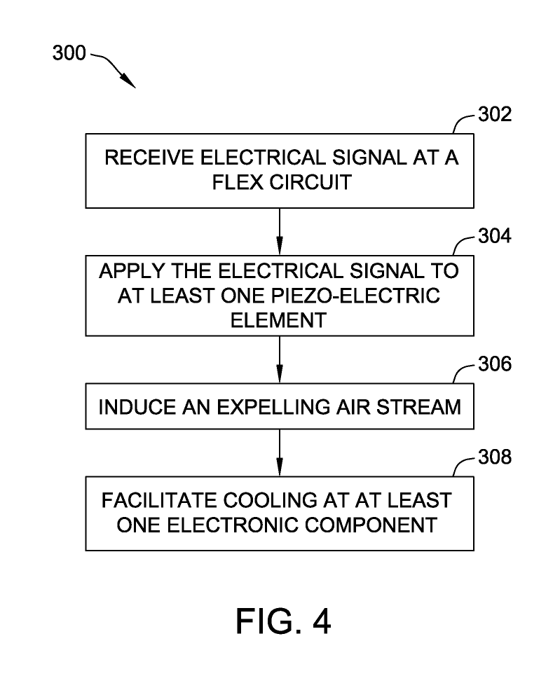

FIG. 4 is a flow chart illustrating an exemplary method 300 of cooling at least one electronic component 130 (shown in FIG. 2) implemented by the synthetic cooling jet system 200 (shown in FIG. 3). In the exemplary embodiment, electrical power source 123 (shown in FIG. 1) is coupled to synthetic cooling jet system 200 including at least one synthetic cooling jet 100 (shown in FIG. 1). The at least one synthetic cooling jet 100 is associated with flex circuit 116 (shown in FIG. 1), and flex circuit 116 receives 302 an electrical signal from electrical power source 123 and applies 304 the electrical signal to piezoelectric element 104 (shown in FIG. 1).

In the exemplary embodiment, the applied electrical signal induces piezoelectric element 104 to expand and compress due to piezoelectric forces. The expanding and contracting piezoelectric element 104 actuates at least one of top plate 106 (shown in FIG. 1) and bottom plate 108 (shown in FIG. 1) to bow, or flex, generating compression and expansion cycles. The compression cycles induce 306 an expelling air stream 128 (shown in FIG. 2) that is expelled through orifice 114 (shown in FIG. 2). The expelling air stream 128 travels in the direction of orifice 114 to at least one electronic component 130 (shown in FIG. 2), and facilitates 308 cooling electronic component 130 by increasing the forced convective heat transfer associated with electronic component 130.

The synthetic jet cooling systems described above facilitate cooling at least one electronic component through forced convective heat transfer. The embodiments described herein also facilitate providing a robust and durable synthetic cooling jet system with redundant connections and a flex circuit. The embodiments described herein also facilitate increased cooling capacity through a modular synthetic cooling jet system.

The synthetic jet cooling system described above includes an electrical power source and at least one synthetic cooling jet coupled to the electrical power source. The at least one synthetic cooling jet includes a pair of plates, also referred to as shims and/or disks, and at least one piezoelectric element. The at least one piezoelectric element is coupled to at least one plate of the pair of plates. In some embodiments, the synthetic cooling jet includes a pair of piezoelectric elements coupled to a respective top plate and bottom plate of the pair of plates. The top plate and the bottom plate define an air gap between the top plate and the bottom plate and further define an orifice along a portion of the outer edge of the top plate and the bottom plate through which air can enter and be expelled.

The at least one synthetic cooling jet described above also includes at least one flex circuit coupled to at least one piezoelectric element and to the electrical power source. The at least one flex circuit receives power from the electrical power source, and transmits an electrical signal to the at least one piezoelectric element. In some embodiments, the synthetic cooling jet includes a top flex circuit and a bottom flex circuit coupled to a respective top plate and a respective bottom plate, each flex circuit also coupled to a respective top piezoelectric element and bottom piezoelectric element. When an electrical signal is applied to the at least one piezoelectric element, the piezoelectric element actuates at least one of the top plate and the bottom plate to bow, or flex, compressing and expanding the air gap. Each compression and expansion cycle induces an expelling air stream or an entering air stream respectively, in a manner similar to a bellows. In the exemplary embodiment, the synthetic cooling jets may be oriented such that the expelling air stream is directed toward the electronic component. The expelling air stream interacts with the air proximate the electronic component to facilitate forced convective heat transfer by the electronic component.

Furthermore, the exemplary synthetic cooling jet system described above may be modular. More specifically, the exemplary synthetic cooling jet system may include a plurality of synthetic cooling jets coupled to respective brackets. Each bracket includes an electrical contact through which an electrically conductive element may be inserted to electrically connect each of the plurality of synthetic cooling jets. In addition, the electrical contact may also electrically connect a flex circuit associated with a top piezoelectric element to a flex circuit associated with a bottom piezoelectric element. The modular synthetic cooling jet system may orient each of the plurality of synthetic cooling jets in substantially the direction of the electronic component to facilitate cooling the electronic component through forced convective heat transfer.

An exemplary technical effect of the methods, systems, and apparatus described herein includes at least one of: (a) facilitating cooling an electronic component with a synthetic cooling jet; (b) improving a robustness of a synthetic cooling jet that includes a flex circuit and robust connections; (c) increasing the cooling capacity of a synthetic cooling jet system by providing a plurality of cooling jets; (d) increasing ventilation for a synthetic cooling jet system by stacking the plurality of synthetic cooling jets; and (e) providing a robust mechanical cover for the synthetic cooling jets.

Exemplary embodiments of modular and robust synthetic cooling jets and synthetic cooling jet systems are described above in detail. The modular and robust synthetic cooling jet systems and methods of operating and manufacturing the same are not limited to the specific embodiments described herein, but rather, components of systems and/or steps of the methods may be utilized independently and separately from other components and/or steps described herein. For example, the synthetic cooling jets may be used to cool non-electronic components or to circulate air for other purposes, and is not limited to cooling electronic components as described herein.

Although specific features of various embodiments may be shown in some drawings and not in others, this is for convenience only. Any feature of a drawing may be referenced and/or claimed in combination with any feature of any other drawing.

This written description uses examples to describe the embodiments of the disclosure, including the best mode, and also to enable any person skilled in the art to practice the systems and methods described herein, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A modular synthetic cooling jet apparatus for cooling at least one electronic component comprising a first synthetic cooling jet, said first synthetic cooling jet comprising:
a first piezoelectric element;
a first pair of plates coupled to said first piezoelectric element, wherein said first pair of plates comprises a first top plate and a first bottom plate;
a first air gap defined between said first top plate and said first bottom plate; and
a first flex circuit coupled to said first piezoelectric element, said first flex circuit configured to be coupled to an electrical power source and to transmit a first electrical signal to said first piezoelectric element, wherein said first piezoelectric element is configured to actuate at least one of said first top plate and said first bottom plate to induce a first expelling air stream.

2. The apparatus in accordance with claim 1 further comprising a second synthetic cooling jet stacked with said first synthetic cooling jet, said second synthetic cooling jet comprising:
a second piezoelectric element;
a second pair of plates coupled to said second piezoelectric element, wherein said second pair of plates comprises a second top plate and a second bottom plate;
a second air gap defined between said second top plate and said second bottom plate; and
a second flex circuit coupled to said second piezoelectric element, said second flex circuit configured to be coupled to the electrical power source and to transmit a second electrical signal to said second piezoelectric element, wherein said second piezoelectric element is configured to actuate at least one of said second top plate and said second bottom plate to induce a second expelling air stream.

3. The apparatus in accordance with claim 2 further comprising a spacer positioned between said first synthetic cooling jet and said second synthetic cooling jet, wherein said spacer defines at least one ventilation hole.

4. The apparatus in accordance with claim 2 further comprising:
a first bracket coupled to said first pair of plates; and
a second bracket coupled to said second pair of plates, wherein said first bracket and said second bracket are configured to receive at least one electrically conductive element that electrically couples said first bracket to said second bracket.

5. The apparatus in accordance with claim 1, wherein said first synthetic cooling jet further comprises a top piezoelectric element coupled to said first top plate and a bottom piezoelectric element coupled to said first bottom plate, and said first flex circuit is coupled to said bottom piezoelectric element and said top piezoelectric element.

6. The apparatus in accordance with claim 1 further comprising at least one suspension coupled to at least one of said first top plate and said first bottom plate and a first bracket, wherein said at least one suspension facilitates damping a vibration of at least one of said first top plate and said first bottom plate.

7. The apparatus in accordance with claim 1, wherein said first flex circuit is redundantly coupled to at least one of said first piezoelectric element, said first top plate, and said first bottom plate at a plurality of contact pads.

8. A method of cooling an electronic component, said method comprising:
receiving electrical power from an electrical power source at a first flex circuit of a first synthetic cooling jet;
transmitting a first electrical signal from the first flex circuit to a first piezoelectric element, wherein the first piezoelectric element is coupled to a first pair of plates that comprise a first top plate and a first bottom plate, the first top plate and the first bottom plate defining a first air gap between the first top plate and the first bottom plate;
actuating at least one of the first top plate and the first bottom plate with the first piezoelectric element to induce a first expelling air stream; and
facilitating cooling the electronic component with the first expelling air stream.

9. The method in accordance with claim 8 further comprising:
stacking a second synthetic cooling jet with the first synthetic cooling jet;
receiving electrical power from the electrical power source at a second flex circuit of the second synthetic cooling jet;
transmitting a second electrical signal from the second flex circuit to a second piezoelectric element, wherein the second piezoelectric element is coupled to a second pair of plates that comprise a second top plate and a second bottom plate, the second top plate and the second bottom plate defining a second air gap between the second top plate and the second bottom plate;
actuating at least one of the second top plate and the second bottom plate with the second piezoelectric element to induce a second expelling air stream; and
facilitating cooling the electronic component with the second expelling air stream.

10. The method in accordance with claim 9, wherein stacking the first synthetic cooling jet with the second synthetic cooling jet includes inserting a spacer between the first synthetic cooling jet and the second synthetic cooling jet, the spacer defining at least one ventilation hole.

11. The method in accordance with claim 8 further comprising:
transmitting the first electrical signal to a top piezoelectric element coupled to the first top plate with a top flex circuit; and
transmitting the first electrical signal to a bottom piezoelectric element coupled to the first bottom plate with a bottom flex circuit.

12. The method in accordance with claim 8 further comprising:
transmitting the first electrical signal to a top piezoelectric element coupled to the first top plate with the first flex circuit; and
transmitting the first electrical signal to a bottom piezoelectric element coupled to the first bottom plate with the first flex circuit.

13. The method in accordance with claim 8 further comprising damping a vibration of at least one of the first top plate and the first bottom plate with at least one suspension coupled to at least one of the first top plate and the first bottom plate and to a first bracket.

14. The method in accordance with claim 8, wherein transmitting the first electrical signal to the first piezoelectric element includes transmitting the first electrical signal to the first piezoelectric element through a plurality of contact pads attached to the first piezoelectric element.

15. A synthetic cooling jet system comprising:
an electrical power source;
an electronic component; and
a first synthetic cooling jet comprising:
a first piezoelectric element;
a first pair of plates coupled to said first piezoelectric element, wherein said first pair of plates comprises a first top plate and a first bottom plate;
a first air gap defined between said first top plate and said first bottom plate; and
a first flex circuit coupled to said first piezoelectric element, the first flex circuit configured to be coupled to said electrical power source and to transmit a first electrical signal to said first piezoelectric element, wherein said first piezoelectric element is configured to actuate at least one of said first top plate and said first bottom plate to induce a first expelling air stream that interacts with said electronic component.

16. The system in accordance with claim 15, wherein said system further comprises a second synthetic cooling jet stacked with said first synthetic cooling jet, said second synthetic cooling jet comprising:
a second piezoelectric element;
a second pair of plates coupled to said second piezoelectric element, wherein said second pair of plates comprises a second top plate and a second bottom plate;
a second air gap defined between said second top plate and said second bottom plate; and
a second flex circuit coupled to said second piezoelectric element, said second flex circuit configured to be coupled to the electrical power source and to transmit a second electrical signal to said second piezoelectric element, wherein said second piezoelectric element is configured to actuate at least one of said second top plate and said second bottom plate to induce a second expelling air stream that interacts with said electronic component.

17. The system in accordance with claim 16 further comprising:
a first bracket coupled to said first pair of plates; and
a second bracket coupled to said second pair of plates, wherein said first bracket and second bracket are configured to receive at least one electrically conductive element that electrically couples said first bracket to said second bracket.

18. The system in accordance with claim 15, wherein said first flex circuit has one of a serpentine structure and a curved structure to facilitate reducing an impedance of movement for at least one of said first top plate and said first bottom plate.

19. The system in accordance with claim 15, wherein said first synthetic cooling jet further comprises a top piezoelectric element coupled to said first top plate and a bottom piezoelectric element coupled to said first bottom plate.

20. The system in accordance with claim 19, wherein said synthetic cooling jet further comprises a top flex circuit coupled to said top piezoelectric element and a bottom flex circuit coupled to said bottom piezoelectric element.
